(19) United States
(12) Patent Application Publication
(10) Pub. No.: US 2019/0379300 A1
(43) Pub. Date: Dec. 12, 2019

(54) RESILIENT WAVE-SHAPED ENERGY-GENERATING DEVICE

(71) Applicant: Nano and Advanced Materials Institute Limited, Hong Kong (HK)

(72) Inventors: Shigu CAO, Hong Kong (HK); Wendan LIU, Hong Kong (HK); Hui LUO, Hong Kong (HK); Li FU, Hong Kong (HK)

(21) Appl. No.: 16/463,851

(22) PCT Filed: Nov. 27, 2017
(86) PCT No.: PCT/CN2017/113178

§ 371 Date: May 24, 2019

Related U.S. Application Data
(60) Provisional application No. 62/497,632, filed on Nov. 28, 2016.

(51) Int. Cl. H02N 1/04; H02N 2/18; H01L 41/08; H01L 41/113; H01L 41/193; H01L 41/18; H01L 41/053; H01L 41/313; H01L 41/45; H01L 41/37

(52) U.S. Cl. CPC H02N 1/04; H02N 2/186; H01L 41/082; H01L 41/1132; H01L 41/37; H01L 41/183; H01L 41/0533; H01L 41/313; H01L 41/45; H01L 41/193

(57) ABSTRACT

An energy-generating device is provided for generating energy by device deformation in any of three orthogonal directions. The device includes a resilient wave-shaped substrate comprising six or more alternating wave structures extending along at least one axis. The resilient wave-shaped substrate is capable of deformation and recovery in three orthogonal directions. Resilient, energy-generating components are mounted on top and bottom surfaces of the resilient wave-shaped structure. The energy-generating components are selected from piezoelectric and triboelectric energy-generating component and output a voltage and current in response to deformation in any of three orthogonal directions. In one aspect, the energy generating device is included in an energy harvester. In another aspect, the energy-generating device is included in a sensor, particularly a sensor for measuring strain. In one aspect a mat of randomly-oriented piezoelectric fibers comprises the energy-generating component.

### FIELD OF THE INVENTION

The invention relates to energy-generating devices and, more particularly, to wave-shaped energy-generating devices that are deformable in any of three orthogonal directions for generating energy from deformations in each of the directions. The energy-generating devices may be incorporated in energy harvesters or sensors.

### BACKGROUND

Energy may be generated from piezoelectric and triboelectric materials. Piezoelectric materials transform mechanical strain into electricity while triboelectric materials produce charge through frictional contact with a different triboelectric material. Energy harvesters exploit these material properties to generate electricity to power electrical devices. To generate sufficient amounts of electricity, many energy harvesters make use of some form of cantilever structure in which a weighted mass vibrates at a resonant frequency. In such a structure, the cantilever is typically fixed at one end. Many different cantilever configurations are employed and a large variety of energy harvester designs are available.

With the widespread use of portable and wearable electronics, there is a continuing need to access power sources to charge personal devices. Energy harvesters are attractive candidates as power sources. However, most energy harvester designs will not generate power from human motions and vibrations, since these motions and vibrations are random, that is, they are not at the resonant frequency of the energy harvester. Further, most energy harvesters incorporate rigid elements that are not comfortable for wear by a user.

Attention has turned to alternative shapes for energy harvesters, rather than a standard cantilever beam fixed at one end. For example, U.S. 2016/0156287 discloses an energy harvester using curved sections having half-piezoelectric ceramic tubes affixed thereto. One end is attached to a vibration source. Although a higher output power is obtained, the overall structure still moves in the same way as a standard cantilever beam and thus still has a resonant frequency.

There is a need in the art for improved energy-generation devices. Particularly, there is a need for energy-generation devices that are portable and responsive to vibration generated by human activity.

### SUMMARY OF THE INVENTION

The present invention provides an energy-generating device for generating energy by device deformation in any of three orthogonal directions. The device includes a resilient wave-shaped substrate comprising six or more alternating wave structures extending along at least one axis. The resilient wave-shaped substrate is capable of deformation and recovery in three orthogonal directions. Resilient, energy-generating components are mounted on top and bottom surfaces of the resilient wave-shaped structure. The energy-generating components are selected from piezoelectric and triboelectric energy-generating component and output a voltage and current in response to deformation in any of three orthogonal directions. In one aspect, the energy generating device is included in an energy harvester. In another aspect, the energy-generating device is included in a sensor, particularly a sensor for measuring strain.

### BRIEF DESCRIPTION OF THE DRAWINGS

FIG. 1 schematically depicts an energy-generating structure according to an embodiment;

FIG. 2 schematically depicts a portion of the energy-generating structure of FIG. 1;

FIG. 3A depicts curvature in one direction; FIG. 3B depicts curvature in two directions.

FIG. 4 schematically depicts a randomly-oriented fiber mat for use in the energy-generating structure of FIG. 1;

FIG. 5 schematically depicts a triboelectric structure for use in the energy-generating structure of FIG. 1;

FIGS. 6A and 6B schematically depict single and stacked energy-generating devices incorporating the energy-generating structure of FIG. 1;

FIG. 7 schematically depicts an exemplary layer structure for the energy-generating device of FIGS. 6A-B;

FIGS. 8A-8F schematically depicts a packaging method for an energy-generating structure according to an embodiment.

### DETAILED DESCRIPTION

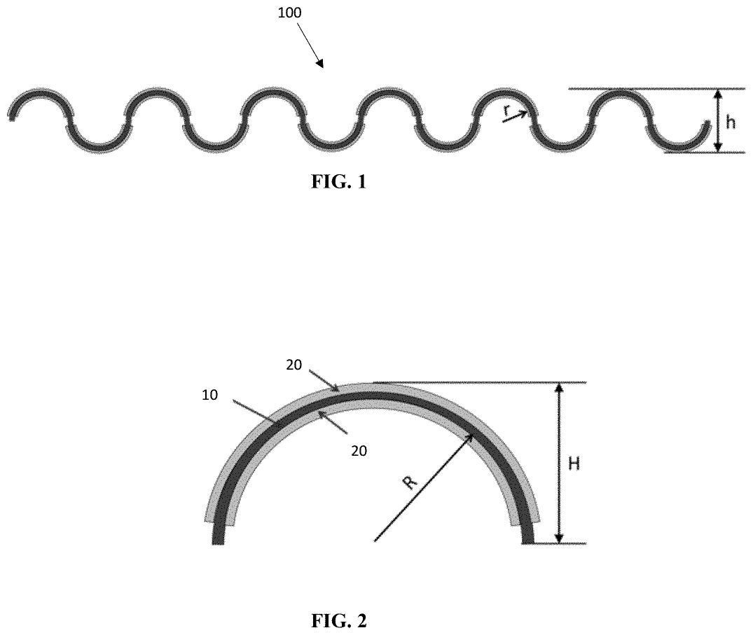

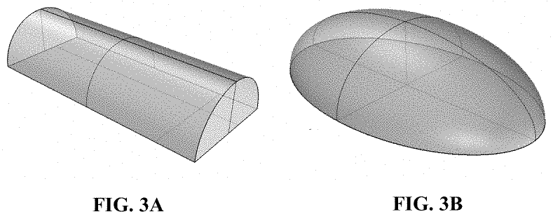

Turning to the drawings in detail, FIG. 1 depicts an energy-generating structure 100 according to an embodiment. As seen in FIG. 1, the energy-generating structure 100 has an overall wave shape, with the structure including six or more alternating waves extending along an axis. A single wave is a complete alternating pattern, as in a sinusoidal wave. Thus, the portion of energy-generating structure 100 seen in FIG. 2 is a half-wave structure, shown in greatly-enlarged form to more easily view the substrate 10 and the energy-generating components 20 mounted on the top and bottom portions of substrate 10. For each direction perpendicular to the surface normal, a curvature can be defined. Among all curvatures of a surface, the largest one and the smallest one are called principal curvatures, which can be proved to be orthogonal to each other. When two principal curvatures of a surface wave are both non-zero, the wave is called a 2-dimensional wave an example of which is shown in FIG. 3B. When only one of the two principal curvatures is zero, the wave is called a one-dimensional wave as shown in FIG. 3A. Both types of waves may be used in the wave-structured substrates 10 of the present invention.

The energy-generating structure 100 is deformable in each of three orthogonal directions; to this end, substrate 10 is a resilient substrate and may be fabricated from a wide variety of materials including polymers, elastomeric polymers, rubbers, fabrics, metals, alloys, and natural flexible materials such as bamboo. In short, any substrate material which, when formed in alternating wave structures, can deform subject to an external loading in any of three orthogonal directions and restore its original shape upon removing the load may be used as a substrate material in the energy-generating structures of the present invention. The wave-shaped substrate may be formed in any of a variety of molding techniques including hot pressing of resilient sheet materials in a wave-shaped mold, injection molding, vacuum forming; any technique capable of forming a resilient wave-shaped substrate 10 may be employed to form the energy-generating structures of the present invention.

Energy generating components 20 are mounted to the top and bottom surfaces of the resilient substrate 10. The resilient, energy-generating components 20 output a voltage and current in response to deformation and are selected from piezoelectric or triboelectric materials. A piezoelectric material is one that outputs a charge in response to mechanical stress while triboelectric materials output a charge in response to frictional contact with a material of an opposite charge.

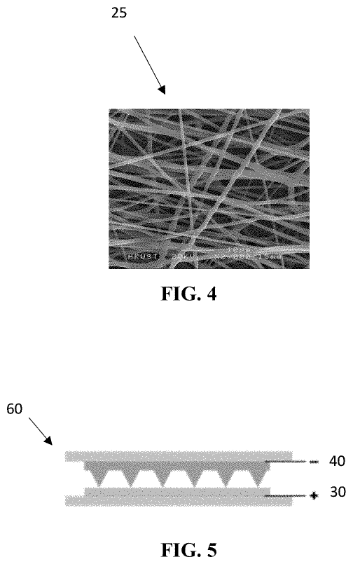

Examples of piezoelectric materials that may be used as the energy-generating components 20 are piezoelectric polymers or organic nanostructures. Examples of piezoelectric polymers include those based on polyvinylidene fluoride (PVDF) including poly(vinylidene fluoride-co-hexafluoropropylene) PVDF-HFP or poly(vinylidenefluoride-co-trifluoroethylene) (PVDF-TrFe). Examples of organic nanostructures include diphenylalanine peptide nanotubes. In one aspect, the piezoelectric materials may be formed into fibers and the fibers disposed in randomly-oriented fiber mats as depicted in FIG. 3. In FIG. 4, deposited fibers 25 are randomly-oriented; in this manner, a deformation in any of three orthogonal directions will produce a charge response. In particular, the deposited fibers may be electrospun fibers or nanofibers. In one aspect, the fibers are electrospun polyvinylidene fluoride-based fibers that are spun with the addition of a lithium-based additive such as LiCl. Details of electrospinning fibers are discussed in the Examples, below.

In a further aspect, the resilient piezoelectric component 20 may include rigid piezoelectric particles or films embedded therein. The resilient component 20 transfers mechanical stress to the rigid piezoelectric materials, which generate a charge response to the stress. A wide variety of piezoelectric materials may be embedded into a resilient layer 20 or resilient fibers 25 including, but not limited to, barium titanate (BTO), bismuth titanate, sodium niobate, bismuth ferrite, quartz, lead titanate, lead zirconate titanate, zinc oxide, lithium niobate, or potassium niobate. In particular, barium titanate particles in electrospun polyvinylidene fluoride-based fibers may be used as resilient electricity-generating component 20.

Triboelectric materials are used in combinations of relatively positively and relatively negatively-charged material pairs. Examples of relatively-positively charged materials that may be used in this embodiment include polyurethane foam, nylon, or acrylic while examples of relatively-negatively charged materials that may be used in this embodiment include polyethylene, polypropylene, vinyl, and silicone rubber. FIG. 5 depicts a triboelectric structure 60 which may be used with pairs of relatively-positively charged materials 30 and relatively-negatively charged materials 40. The structure may be incorporated as part of layer 20 in energy-producing structure 100.

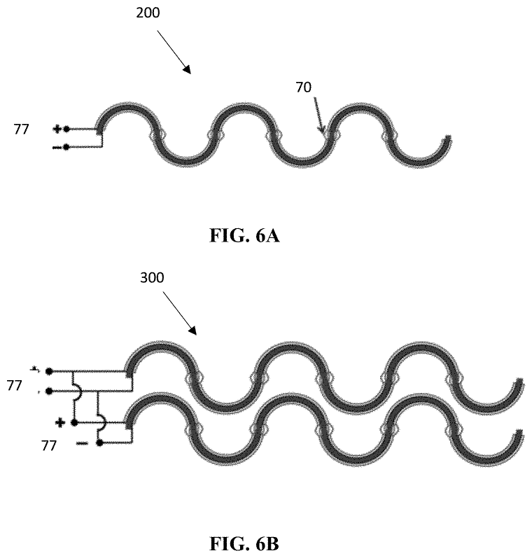

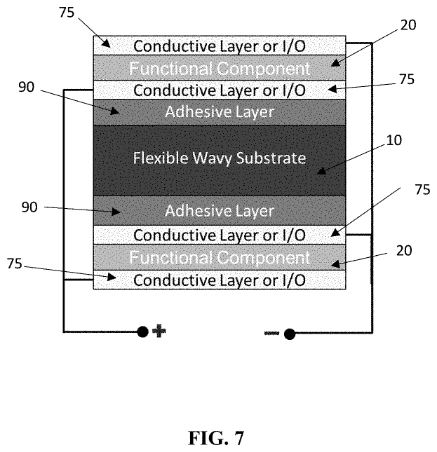

FIGS. 6A and 6B depict energy-generating device 200 and stacked energy-generating device 300 incorporating the energy-generating structure 100 of FIG. 1. FIG. 7 depicts an exemplary structure of layers of the device of FIGS. 6A and 6B. Electrical connection points 70 of FIGS. 6A and 6B connect to the electrical contact layers 75 of FIG. 7. As each half-wave structure deforms, opposite charges are generated (compressive force vs. tensile force in each half wave for an applied force in a given direction). Thus, positioning the contacts at each half-wave point collects the charge of the same kind. Electrical leads 77 may connect to a battery, capacitor, or charge-measuring device. Adhesive layers 90 (FIG. 7) adhere the energy-generating component layers 20 to the wave-shaped substrate 10 and help to transfer the mechanical deformation stress from the substrate 10 to the layers 20. As discussed in Example 1 below, electrical contact layers 75 may be provided on each side of the energy-generating component layers 20. For the stacked structures of FIG. 6B, series connection results in a higher voltage output, and parallel connection results in a higher current output.

Because the energy-generating structures of the present invention are deformable in any of three orthogonal directions, they can easy generate charge as energy harvesters when worn by a person performing ordinary activity. For example, a sleeve formed from the energy-generating structures may be placed around an elbow or knee and the structures will be repeatedly compressed in various directions, generating charges that may be stored in a battery or capacitor. Thus the structures of the present invention generate energy from random and non-repetitive motions, such as movements with a frequency of under 5 Hz.

Using large numbers of wave structures in a substrate may generate high piezoelectric performance with voltage output >100V and current output >5 μA/cm² for an individual energy-generating structure.

Advantageously, wave structures may be stacked together to make packages with higher current density, i.e., >20 μA/cm² with 5 structures stacked together.

In another aspect, the energy-generating structures of the present invention may be used as sensors. The output charge is correlated to the strain experienced by the energy-generating structure. Larger strain in the structure may produce higher charge generation, thus higher energy output for the energy-generating structure. When the energy-generating structure is used as a sensor the voltage output correlates with the strain experienced. Further advantages of the present invention can be seen in the Examples set forth below:

### EXAMPLE 1

### Fabrication of Piezoelectric Fibers

In one embodiment, the energy-producing component 20 may be piezoelectric fibers. In particular, electrospun piezoelectric fibers may be used. In this process, a polymer solution is fed to a spinneret in an electrospinning machine, such as the commercially-available NANON 01A Electrospinning Machine.

Polymer Solution Preparation

Solvent DMF and acetone in a weight ratio of 6:4 are mixed with an optional additive to tune the conductivity of solution, magnetic stir for 5 min. Then polymeric polyvinylidene fluoride-based powders are added into the mixed solvent, with a typical concentration of PVDF-HFP around 12.5 wt. %, and that of PVDF-TrFe around 15 wt. %. To dissolve the polymer, the solution is stirred in 85° C. water bath for 2 hrs. After the polymer is thoroughly dissolved, the solution is cooled down to ambient temperature for electrospinning.

Electrospinning

Before electrospinning, relative humidity is controlled to about 30%, and temperature to about 25° C. in the chamber. Aluminum foil is fixed to the scroll in the chamber as the substrate of nanofibers. The parameters are set as below (Table 1):

TABLE 1
Parameters of electrospinning process for PVDF based fiber

| | Condition | | | | | |
|---|---|---|---|---|---|---|
| | | | | | Width | Speed |
| | | | | | of | of |
| | Volt- | | | | spin- | spin- |
| Materials | age | Feed rate | Height | Spin- | neret | neret |
| Polymers | (kV) | (ml/hour) | (mm) | neret | (mm) | (mm/sec) |
| PVDF-HFP | 30 | 6 | 150 | 8-hole | 120 | 50 |
| PVDF-TrFe | 30 | 11.5 | 135 | 8-hole | 120 | 50 |

To improve piezoelectric performance, the following modifications may be made:

1. Adding nanoparticles of barium titanate (BTO) into PVDF may improve the crystal structure of the resultant electrospun nanofibers.

2. Adding LiCl into PVDF-HFP solution results in formation of piezoelectric fibers without any post-treatment process such as a poling process to align the electric dipole. PVDF may take any of the following forms for crystallization: α, β, γ and δ, whose piezoelectric properties are quite different from each another. Although the most commonly obtained type is a type with much lower polarization density compared to β type, β type shows better piezoelectric properties. The crystallization form is related to detailed electrospinning condition, like voltage, needle-substrate distance, evaporation rate, etc. By adjusting these conditions, β crystallization may be obtained. LiCl may increase the conductivity of the solution and enhance the uniformity of the electrical field during spinning, thus promote the crystallization of PVDF.

Randomly aligned PVDF-BTO nanofibers on a wave-structured substrate yield properties of 7.92 v/cm² and 1.27 ua/cm² under 5 Hz operation frequency.

### EXAMPLE 2

### Packaging Fibers to Form Energy-Generating Device

Electronic Packaging

Mats of electrospun fibers or any other fiber configuration may be packaged for enhanced electrical performance as well as for protection of the fibers from both environmental and mechanical damage. In one aspect, a fiber structure may be unified to form an integrated body with a matrix component such as a polymer resin to more readily transfer stress among the fibers and from the flexible substrate to the fibers. In particular, dielectric polymers may act as both a stress/strain intermediary and a protection layer. Epoxy, polyurethane, polyvinyl chloride, and polydimethylsiloxane (PDMS). PMDS are particular examples.

To apply PDMS to a mat of PVDF-BTO fibers, the following process is followed:

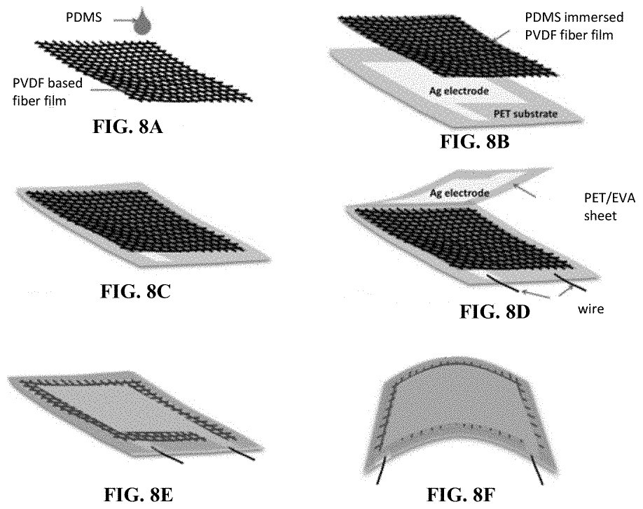

PDMS resin and curing agent are mixed together in a weight ratio of 10:1. The PDMS-curing agent mixture is spread onto a PVDF-BTO fiber mat (FIG. 8A), and saturates the structure, filling in the gaps between the fibers. An electrode is deposited onto a bonding film such as PET the PDMS-impregnated fiber structure is positioned thereon (FIG. 8B); in this example, silver paste may be used but evaporation of electrode films and other electrode-forming techniques may be used. Curing of the PDMS-impregnated fiber mat/PET electrode structure is performed at approximately 60° C. for approximately 2 hours (FIG. 8C). A second electrode-coated sheet is placed on the cured PDMS-fiber mat structure (FIG. 8D) followed by hot pressing (FIG. 8E) to unify the multilayer structure. The electrode-coated cured structure is then adhered to the wave-shaped resilient substrate 10 with an adhesive layer (FIG. 8F).

Throughout this specification, unless the context requires otherwise, the word “include” or “comprise” or variations such as “includes” or “comprises” or “comprising”, will be understood to imply the inclusion of a stated integer or group of integers but not the exclusion of any other integer or group of integers. It is also noted that in this disclosure and particularly in the claims and/or paragraphs, terms such as “included”, “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the present invention.

Furthermore, throughout the specification and claims, unless the context requires otherwise, the word “include” or variations such as “includes” or “including”, will be understood to imply the inclusion of a stated integer or group of integers but not the exclusion of any other integer or group of integers.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

1. An energy-generating device for generating energy by device deformation in any of three orthogonal directions, comprising:
a resilient wave-shaped substrate comprising six or more alternating wave structures extending along at least one axis, the resilient wave-shaped substrate being capable of deformation and recovery in three orthogonal directions;
resilient energy-generating components mounted on top and bottom surfaces of the resilient wave-shaped structure, the energy-generating components being selected from piezoelectric and triboelectric energy-generating components, the resilient energy-generating components outputting a voltage and current in response to deformation in any of three orthogonal directions.

2. The energy-generating device of claim 1, wherein the resilient energy-generating components are piezoelectric fibers.

3. The energy-generating device of claim 2, wherein the fibers are randomly-oriented fibers in one or more fiber mats mounted to the top and bottom surfaces of the resilient wave-shaped substrate.

4. The energy-generating device of claim 3, wherein the fiber mats are impregnated with one or more polymer resins to create an impregnated mat.

5. The energy-generating device of claim 2, wherein the fibers are polyvinylidene fluoride-based fibers.

6. The energy-generating device of claim 5 where the polyvinylidene fluoride-based fibers include one or more of poly(vinylidene fluoride-co-hexafluoropropylene) or poly[vinylidenefluoride-co-trifluoroethylene].

7. The energy-generating device of claim 2, wherein the piezoelectric fibers include particles embedded therein.

8. The energy-generating device of claim 7, wherein the particles are piezoelectric particles.

9. The energy-generating device of claim 8, wherein the piezoelectric particles are selected from barium titanate, bismuth titanate, sodium niobate, bismuth ferrite, quartz, lead titanate, lead zirconate titanate, zinc oxide, lithium niobate, or potassium niobate.

10. The energy-generating device of claim 2, wherein the piezoelectric fibers are electrospun piezoelectric fibers.

11. The energy-generating device of claim 10, wherein the electrospun piezoelectric fibers are polyvinylidene fluoride-based piezoelectric fibers spun with a material including lithium.

12. The energy-generating device of claim 11, wherein the material including lithium is LiCl.

13. The energy-generating device of claim 1, further comprising at least a second resilient wave-shaped substrate with resilient energy-generating components mounted thereto stacked on the resilient wave-shaped substrate with the resilient energy-generating components mounted thereto.

14. The energy-generating device of claim 1, wherein the resilient wave-shaped substrate has curvature in two orthogonal in-plane directions.

15. The energy generating device of claim 1, wherein portions of the resilient energy-generating components are electrically connected in a parallel connection configuration.

16. The energy generating device of claim 1, wherein portions of the resilient energy-generating components are electrically connected in a series connection configuration.

17. A sensor comprising the energy-generating device of claim 1, further including electrical connections to the resilient energy-generating components for outputting a signal indicative of the amount of deformation undergone by the energy-generating device.

18. An energy harvester comprising the energy-generating device of claim 1, further including electrical connections to the resilient energy-generating components for contact with an energy-storage device.

19. The energy harvester of claim 18, wherein the energy storage device is a battery.

20. The energy-generating device of claim 4 wherein the polymer resin is polydimethylsiloxane.
